(19) United States
(12) Patent Application Publication
(10) Pub. No.: US 2023/0097687 A1
(43) Pub. Date: Mar. 30, 2023

(54) ADDITIVE MANUFACTURED ARTICLES HAVING COATED SURFACES AND RELATED METHODS

(71) Applicant: ENTEGRIS, INC., Billerica, MA (US)

(72) Inventor: Carlo Waldfried, Middleton, MA (US)

(21) Appl. No.: 17/950,941

(22) Filed: Sep. 22, 2022

Related U.S. Application Data
(60) Provisional application No. 63/250,503, filed on Sep. 30, 2021.
(60) Provisional application No. 63/336,117, filed on Apr. 28, 2022.

(51) Int. Cl. B29C 64/30; C23C 16/455; C23C 16/40

(52) U.S. Cl. CPC B29C 64/30; C23C 16/45525; C23C 16/405; B33Y 10/00

(57) ABSTRACT

Some embodiments relate to additive manufactured articles having coated surfaces and related methods. The methods may comprise forming a three-dimensional (3D) article by additive manufacturing to obtain an additive manufactured 3D article having a monolithic structure that is not capable of construction by machining, and exposing the additive manufactured 3D article to one or more precursor gases to form a coating layer on a surface of the additive manufactured 3D article. The additive manufactured articles may comprise an additive manufactured three-dimensional (3D) body. The additive manufactured 3D body may have a monolithic structure that is not capable of construction by machining. The additive manufactured 3D body may have a coating layer on a surface of the additive manufactured 3D body.

### CROSS-REFERENCE TO RELATED APPLICATIONS

This application claims the benefit under 35 USC 119 of U.S. Provisional Patent Application Nos. 63/250,503, filed Sep. 30, 2021, and 63/336,117 filed on Apr. 28, 2022, the disclosure of each is hereby incorporated herein by reference in its entirety.

### FIELD

This disclosure generally relates to additive manufactured articles having coated surfaces and related methods.

### BACKGROUND

Machining processes do not permit the manufacture of devices or device components of unitary construction. For example, a device component having a complex shape can only be manufactured by assembling multiple components. The assembly of multiple components often results in seams or welds formed at the interface of two or more components.

### SUMMARY

In a first aspect a method for forming an article is disclosed including: forming a three-dimensional (3D) article by additive manufacturing to obtain an additive manufactured 3D article, wherein the additive manufactured 3D article has a monolithic structure that is not capable of construction by machining; and exposing the additive manufactured 3D article to one or more precursor gases to form a coating layer on a surface of the additive manufactured 3D article, wherein the coating layer is formed by a non-plasma-based deposition process.

A second aspect according to the first aspect, wherein the additive manufactured 3D article has an aspect ratio of 5:1 to 1000:1, wherein the aspect ratio is a ratio of two of a width, a depth, a height, or a diameter.

A third aspect according to any of the preceding aspects, wherein the forming includes dispensing a 3D printable material from a 3D printer to form the additive manufactured 3D article.

A fourth aspect according to any of the preceding aspects, wherein the 3D printable material includes at least one of a metal powder, a metal alloy powder, a ceramic powder, a thermoplastic polymer, or any combination thereof.

A fifth aspect according to any of the preceding aspects, wherein the additive manufactured 3D article is an article of unitary construction.

A sixth aspect according to any of the preceding aspects, wherein the additive manufactured 3D article includes at least one of a plenum, a trench, a structure defining a hole, a structure defining a channel, a structure defining a cavity, or any combination thereof.

A seventh aspect according to any of the preceding aspects, wherein the additive manufactured 3D article does not include seams.

An eighth aspect according to any of the preceding aspects, wherein the additive manufactured 3D article does not include braze joints.

A ninth aspect according to any of the preceding aspects, wherein the additive manufactured 3D article does not include weld joints.

A tenth aspect according to any of the preceding aspects, wherein the coating layer is formed by a thermal atomic layer deposition (ALD) process, a chemical vapor deposition (CVD) process, or a solution deposition process.

An eleventh aspect according to any of the preceding aspects, wherein the coating layer includes at least one of alumina, yttria, titania, zirconia, tantalum oxide, or any combination thereof.

A twelfth aspect according to any of the preceding aspects, wherein the method further including fluorinating the coating layer to form a coating layer including at least one of YOF, YF₃, or any combination thereof.

A thirteenth aspect according to any of the preceding aspects, wherein the coating layer includes an oxide of formula MO, wherein M is Ca, Mg, or Be; an oxide of formula M′O₂, wherein M′ is a stoichiometrically acceptable metal; an oxide of formula Re₂O₃, wherein Re is a rare earth element; or an oxide of formula TaₓO_{y}, where x is greater than 0 and y is greater than 0.

A fourteenth aspect according to any of the preceding aspects, wherein the techniques described herein relate to a method, wherein the coating layer includes an aluminum-oxy nitride; a yttria-alumina; a silicon oxide; a silicon oxy-nitride; a transition metal oxide; a transition metal oxy-nitride; a rare earth metal oxide; a rare earth metal oxy-nitrides; or any combination thereof.

In a fifteenth aspect disclosed herein is a component of a semiconductor manufacturing tool comprising an article formed according to the methods disclosed herein.

In a sixteenth aspect an article is disclosed herein including: an additive manufactured three-dimensional (3D) body, wherein the additive manufactured 3D body has a monolithic structure that is not capable of construction by machining; and a coating layer on a surface of the additive manufactured 3D body, wherein the coating layer is a non-plasma coating layer.

A seventeenth aspect according to the sixteenth aspect, wherein the additive manufactured 3D body has an aspect ratio of 2:1 to 1000:1, wherein the aspect ratio is a ratio of two of a width, a depth, a height, or a diameter.

An eighteenth aspect according to the sixteenth or seventeenth aspect, wherein the non-plasma coating layer is a thermal atomic layer deposition (ALD) coating layer.

A nineteenth aspect according to any one of the sixteenth through eighteenth aspects, wherein the additive manufactured 3D body is a body of unitary construction.

A twentieth aspect according to any one of the sixteenth through nineteenth aspects, wherein the additive manufactured 3D article includes at least one of a plenum, a trench, a structure defining a hole, a structure defining a channel, a structure defining a cavity, or any combination thereof.

In a twenty-first aspect, a medical device is disclosed comprising: an additive manufactured three-dimensional (3D) body having a monolithic structure; and a non-plasma coating layer on at least a portion of a surface of the additive manufactured 3D body.

A twenty-second aspect according to the twenty-first aspect, wherein the medical device is configured for implantation into a mammal.

A twenty-third aspect according to the twenty-first aspect, wherein the medical device is configured for temporary insertion into a mammal.

A twenty-fourth aspect according to the twenty-first aspect, wherein the medical device is configured for external use on a mammal.

A twenty-fifth aspect according to any of the twenty-first to the twenty-fourth aspects, wherein the additive manufactured 3D body is biocompatible.

A twenty-sixth aspect according to any of the twenty-first to the twenty-fifth aspects, wherein the additive manufactured 3D body is a body of the medical device.

A twenty-seventh aspect according to any of the twenty-first to the twenty-fifth aspects, wherein the additive manufactured 3D body is a component of the medical device.

A twenty-eighth aspect according to any of the twenty-first to the twenty-seventh aspects, wherein the additive manufactured 3D body is at least one of a balloon, a graft, a stent, a catheter, a shunt, an embolic agent, a pacemaker, a defibrillator, an artificial implant, a prosthetic, a stimulator, a sensor, a wire, a lead, a valve, a plug, a pump, a filter, a mechanical connector, a tube, a plate, a surgical tool, an enclosure, any component thereof, or any combination thereof.

A twenty-ninth aspect according to any of the twenty-first to the twenty-eighth aspects, wherein the additive manufactured 3D body is at least one of an angioplasty balloon, a valvuloplasty balloon, a deployment balloon, a pacemaker lead, a prosthetic heart valve, a vascular filter, a vascular plug, an artificial heart valve, an artificial heart, a catheter tip, a suture, a surgical staple, a screw, a nail, a bracket, a pin, a rod, a fixture, a guide wire, a drug pump, a synthetic vessel graft, a vascular graft, a nonvascular graft, a stent graft, a vascular stent, a coronary stent, a peripheral stent, an intraluminal paving stent, an arteriovenous shunt, an aneurysm filler, an implantable pulse generator, an implantable cardiac defibrillator, a cardioverter defibrillator, a spinal stimulator, a brain stimulator, a sacral nerve stimulator, a bone prosthetic, a joint prosthetic, a plastic tubing, a metal tubing, a dental braces, a hearing aid, a bandage, any component thereof, or any combination thereof.

A thirtieth aspect according to any of the twenty-first to the twenty-ninth aspects, wherein the additive manufactured 3D body comprises a structure having an aspect ratio of 2:1 to 1000:1, wherein the aspect ratio is a ratio of two of a width, a depth, a height, or a diameter.

A thirty-first aspect according to any of the twenty-first to the thirtieth aspects, wherein the additive manufactured 3D body is an article of unitary construction.

A thirty-second aspect according to any of the twenty-first to the thirty-first aspects, wherein the additive manufactured 3D body does not comprise seams.

A thirty-third aspect according to any of the twenty-first to the thirty-second aspects, wherein the additive manufactured 3D body does not comprise braze joints.

A thirty-fourth aspect according to any of the twenty-first to the thirty-third aspects, wherein the additive manufactured 3D body does not comprise weld joints.

A thirty-fifth aspect according to any of the twenty-first to the thirty-fourth aspects, wherein the non-plasma coating layer is a thermal atomic layer deposition (ALD) coating layer, a chemical vapor deposition (CVD) coating layer, or a solution deposition coating layer.

A thirty-sixth aspect according to any one of the twenty-first to the thirty-fifth aspects, wherein the non-plasma coating layer comprises at least one of alumina, yttria, titania, zirconia, tantalum oxide, or any combination thereof.

A thirty-seventh aspect according to any of the twenty-first to the thirty-sixth aspects, wherein the non-plasma coating layer comprises at least one of YOF, YF₃, or any combination thereof.

A thirty-eighth aspect according to any of the twenty-first to the thirty-seventh aspects, wherein the non-plasma coating layer comprises at least one of: an oxide of formula MO, wherein M is Ca, Mg, or Be; an oxide of formula M′O₂, wherein M′ is a metal; an oxide of formula Re₂O₃, wherein Re is a rare earth element; an oxide of formula TaₓO_{y}, where x is greater than 0 and y is greater than 0; or any combination thereof.

A thirty-ninth aspect according to any of the twenty-first to the thirty-eighth aspects, wherein the non-plasma coating layer comprises at least one of an aluminum-oxy nitride; an yttria-alumina; a silicon oxide; a silicon oxy-nitride; a transition metal oxide; a transition metal oxy-nitride; a rare earth metal oxide; a rare earth metal oxy-nitrides; or any combination thereof.

A fortieth aspect according to any of the twenty-first to the thirty-ninth aspects, wherein the monolithic structure is not capable of construction by machining.

### BRIEF DESCRIPTION OF THE DRAWINGS

Reference is made to the drawings that form a part of this disclosure, and which illustrate embodiments in which the materials and methods described herein can be practiced.

FIG. 1 is a flowchart of a method for forming an article, according to some embodiments of the present disclosure.

FIG. 2 is a schematic diagram of a cross-section of an article, according to some embodiments of the present disclosure.

FIG. 3 is a schematic diagram of a cross-section of an article, according to some embodiments of the present disclosure.

### DETAILED DESCRIPTION

Embodiments of the present disclosure relate to, among other things, articles formed by additive manufacturing, methods of forming articles by additive manufacturing, applications involving articles formed by additive manufacturing, and related embodiments. Some embodiments of the present disclosure relate to additive manufactured articles having one or more coated surfaces. In some embodiments, the articles formed by additive manufacturing may have at least one of a monolithic structure, one or more high aspect ratio features, or any combination thereof. In some embodiments, following fabrication of the article by additive manufacturing, the article may be subjected to a deposition process, such as an atomic layer deposition (ALD) process or a thermal ALD process, in which one or more surfaces of the additive manufactured article is coated with one or more layers. In some embodiments, the deposition process is sufficient to coat all exposed surfaces of the additive manufactured articles. In some embodiments, the coated surface(s) of the additive manufactured article provides at least one of a corrosion resistant layer, an etch resistant layer, or any combination thereof.

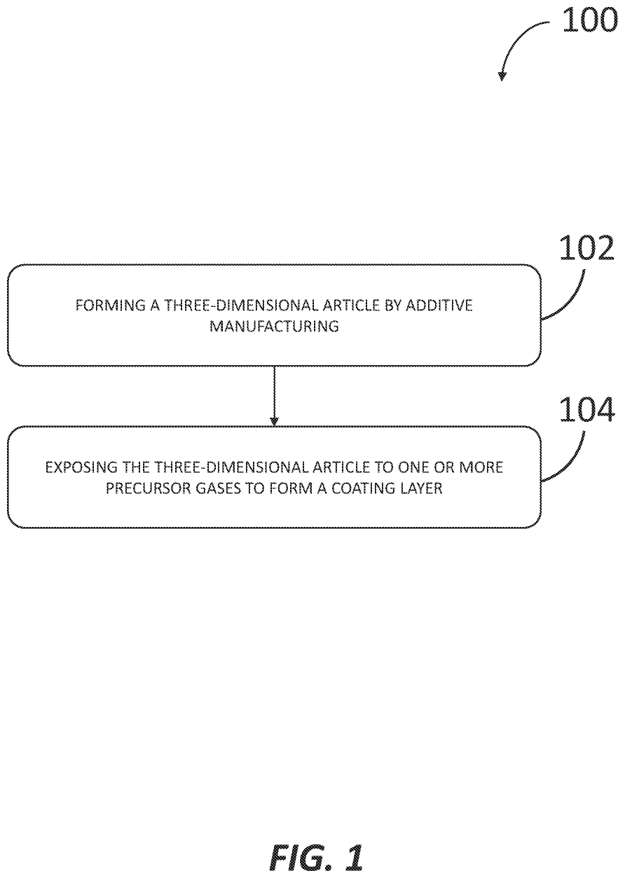

FIG. 1 is a flowchart of a method for forming an article, according to some embodiments of the present disclosure. As shown in FIG. 1, the method 100 for forming an article may comprise one or more of the following steps: a step 102 of forming a three-dimensional (3D) article by additive manufacturing; and a step 104 of exposing the 3D article to one or more precursor gases to form a coating layer.

At step 102, in some embodiments, the method 100 may comprise forming a 3D article by additive manufacturing. In some embodiments, the additive manufacturing may comprise 3D printing. In some embodiments, the 3D article is formed by dispensing a 3D printable material from a 3D printer to form the 3D article. In some embodiments, the 3D printing may comprise creating a solid object from a 3D model by building the object incrementally. In some embodiments, for example, 3D printing may comprise applying the 3D printable material in layers which are selectively joined or fused together to create a 3D article having at least one of a monolithic structure, a unitary construction, a structure not capable of construction by machining, or any combination thereof. The 3D printing may be performed by at least one of the following: selective laser melting (SLM), selective laser sintering (SLS), fused deposition modeling (FDM), electron beam melting (EBM), direct metal laser sintering (DMLS), or any combination thereof.

In some embodiments, the 3D article may be formed from a precursor material. In some embodiments, the precursor material may comprise, consist of, or consist essentially of a 3D printable material. In some embodiments, the precursor material comprises a raw material, such as a granular raw material. For example, in some embodiments, the precursor material may comprise at least one of a metal powder, a metal alloy powder, a ceramic powder, a polymer (e.g., a photopolymer resin, a thermoplastic polymer, or any combination thereof), or any combination thereof. In some embodiments, the precursor material may comprise a material capable of being fused by heat (e.g., a scanning laser or scanning electron beam). In some embodiments, the precursor material may comprise, consist of, or consist essentially of a metal component. In some embodiments, the metal component may comprise, consist of, or consist essentially of at least one of one or more metals, one or more metal compounds, one or more metal oxides, one or more metal alloys, or any combination thereof. In some embodiments, the precursor material may comprise, consist of, or consist essentially of, or may be selected from the group consisting of, at least one of the following: Al, Mg, Ni, Ti, V, Fe, Cr, Zn, Mo, Li, Cu, Mn, In, Sn, P, Sb, As, Bi, Pb, Te, Se, W, Ge, Cd, Co, Ag, Pt, Hg, Ir, Os, S, K, Ga, Na, Nb, Ta, Si, La₂O₃, NiO, Fe₂O₃, Al₂O₃, BaO, MgO, CaO, HfO₂, ZrO₂, SnO₂, In₂O₃, K₂O, CeO₂, Ce₂O₃, Sc₂O₃, Y₂O₃, Ga₂O₃, Na₂O, B₂O₃, SrO, BeO, titanium oxides, tantalum oxides, niobium oxides, silicon carbide, stainless steel, rare earth oxides, a component thereof, or any combination thereof. In some embodiments, the precursor material may comprise one or more solvents.

In some embodiments, the 3D article may comprise an additive manufactured 3D article. In some embodiments, the 3D article may comprise an additive manufactured 3D body. In some embodiments, the 3D article may have a monolithic structure. In some embodiments, a monolithic structure may be a structure that is not capable of construction by machining. In some embodiments, the term “machining” may refer to a process of shaping a material by, for example and without limitation, milling, grinding, cutting, carving, chipping, or forming, among other things. In some embodiments, a monolithic structure may be a structure of unitary construction. In some embodiments, the 3D article may be of unitary construction. In some embodiments, the term “unitary construction” may refer to a structure that does not comprise two or more structures joined together post-fabrication. For example, in some embodiments, the 3D article may not comprise any structures that are separately fabricated and subsequently joined together. In some embodiments, a monolithic structure of unitary construction may be a structure that does not comprise seams. In some embodiments, a monolithic structure of unitary construction may be a structure that does not comprise braze joints. In some embodiments, a monolithic structure of unitary construction may be a structure that does not comprise weld joints.

In some embodiments, the 3D article may have at least one feature. In some embodiments, the at least one feature may comprise, consist of, or consist essentially of, or may be selected from the group consisting of, a plenum, a trench, a structure defining a hole, a structure defining an opening, a structure defining a channel, a structure defining a cavity (e.g., a partially enclosed region defining a cavity), a planar surface, a non-planar surface, or any combination thereof. In some embodiments, the at least one feature may have an aspect ratio. For example, in some embodiments, the aspect ratio of a feature may refer to a ratio of a depth to a width. In some embodiments, the aspect ratio of a feature may refer to a ratio of a width to a depth. In some embodiments, the aspect ratio of a feature may refer to a ratio of two of a length, a width, or a height. In some embodiments, the aspect ratio of a feature may refer to a ratio of a depth to a diameter. In some embodiments, the aspect ratio of a feature may refer to a ratio of a diameter to a depth. In some embodiments, the aspect ratio of a feature may refer to a ratio of at least two of the following: a width, a depth, a height, a diameter, and a circumference.

In some embodiments, the at least one feature may have an aspect ratio of 2:1 to 1000:1, or any range or subrange therebetween. For example, the at least one feature may have an aspect ratio of at least 2:1, at least 3:1, at least 4:1, at least 5:1, at least 6:1, at least 7:1, at least 8:1, at least 9:1, at least 10:1, at least 15:1, at least 20:1, at least 25:1, at least 30:1, at least 35:1, at least 40:1, at least 45:1, at least 50:1, at least 55:1, at least 60:1, at least 65:1, at least 70:1, at least 75:1, at least 80:1, at least 85:1, at least 90:1, at least 95:1, at least 100:1, at least 200:1, at least 300:1, at least 400:1, at least 500:1, at least 600:1, at least 700:1, at least 800:1, at least 900:1, to 1000:1, and/or any range or subrange therebetween.

In some embodiments, the 3D article may be a component of a semiconductor manufacturing tool, such as, for example and without limitation, at least one of a process chamber, a sidewall, a flow head (e.g., a showerhead), a shield, a tray, a support, a nozzle, a valve, a conduit, a stage for handling or holding an object, a wafer handling fixture, a ceramic wafer carrier, a wafer holder, a susceptor, a spindle, a chuck, a ring, a baffle, a fastener (e.g., a (threaded) screw, a (threaded) nut, a bolt, a clamp, a rivet, etc.), a membrane, a filter, a three-dimensional network, a conduit (e.g., a gas line), a manifold (e.g., a gas manifold), or any combination thereof.

At step 104, in some embodiments, the method 100 may comprise exposing the 3D article to one or more precursor gases to form a coating layer. In some embodiments, the method 100 may comprise exposing the additive manufactured 3D article to one or more precursor gases to form a coating layer on a surface of the additive manufactured 3D article. In some embodiments, the coating layer may be formed by a deposition process. In some embodiments, the deposition process may comprise a non-plasma deposition process. In some embodiments, the deposition process may comprise a plasma-free deposition process. In some embodiments, the deposition process may comprise an atomic layer deposition process. In some embodiments, the atomic layer deposition process may comprise a thermal atomic layer deposition process. Accordingly, in some embodiments, the coating layer may comprise an atomic layer deposition coating layer, or ALD coating layer. In some embodiments, the coating layer may comprise a non-plasma coating layer (e.g., a coating layer not formed by a plasma deposition process). In some embodiments, the coating layer may comprise a thermal atomic layer deposition coating layer, or thermal ALD coating layer. In some other embodiments, the deposition process may comprise at least one of chemical vapor deposition (CVD), solution deposition (e.g, sol-gel deposition, dip coatings, etc.), electrolytic-based coating methods, or any combination thereof.

In some embodiments, the exposing may comprise a process sequence for atomic layer deposition. In some embodiments, the process sequence may be one in which the one or more precursors are utilized in a cyclic atomic layer deposition (ALD) process to form the ALD coating layer or thermal ALD coating layer. In some embodiments, the exposing may comprise a process sequence of contacting the 3D article with at least a first precursor in a reaction chamber, purging the reaction chamber, contacting the 3D article with at least a second precursor in the reaction chamber, and purging the reaction chamber to complete a cycle. In some embodiments, the exposing may comprise from 1 to 5000 cycles. In some embodiments, the exposing may comprise 100 to 5000 cycles. In some embodiments, the exposing may comprise 50 to 1500 cycles. In some embodiments, the exposing may comprise a sufficient number of cycles to achieve a desired thickness, a desired property, or other characteristic.

In some embodiments, the one or more precursor gases may be selected based on the specific ALD coating layer to be formed. In some embodiments, the one or more precursors comprising trimethylaluminum and ozone may be useful precursor compositions for depositing Al₂O₃. In some embodiments, the one or more precursors comprising trimethylaluminum and water may be useful precursor compositions for depositing Al₂O₃. In some embodiments, the one or more precursors comprising cyclopentadienyl compounds of the metal M or of Ln may be useful precursor compositions for depositing MO or Ln₂O₃ in cyclic ALD processes utilizing ozone (O₃) or water vapor (H₂O). In some embodiments, the one or more precursors comprising beta-diketonates of M or Ln may be useful precursor compositions for depositing MO or Ln₂O₃ in a cyclic ALD process in which reactive pulses of the beta-diketonate metal precursor alternate with pulses of O₃.

For example, in some embodiments, the atomic layer deposition may comprise a process sequence in which trimethylaluminum and ozone are utilized in a cyclic ALD process to form the ALD coating layer. In some embodiments, the atomic layer deposition may comprise a process sequence in which trimethylaluminum and water are utilized in a cyclic ALD process to form the ALD coating layer. In some embodiments, the atomic layer deposition may comprise a process sequence in which a cyclopentadienyl M compound and ozone are utilized in a cyclic ALD process to form the ALD coating layer. In some embodiments, the atomic layer deposition may comprise a process sequence in which a cyclopentadienyl M compound and water are utilized in a cyclic ALD process to form the ALD coating layer. In some embodiments, the atomic layer deposition may comprise a process sequence in which a M beta-diketonate compound and ozone are utilized in a cyclic ALD process to form the ALD coating layer. In some embodiments, other metal oxide precursor compounds may be used.

In some embodiments, the one or more precursors comprising trimethylaluminum and ozone may be useful precursor compositions for depositing Al₂O₃. In some embodiments, the one or more precursors comprising trimethylaluminum and water may be useful precursor compositions for depositing Al₂O₃. In some embodiments, the one or more precursors comprising cyclopentadienyl compounds of the metal M or of Ln may be useful precursor compositions for depositing MO or Ln₂O₃ in cyclic ALD processes utilizing ozone (O₃) or water vapor (H₂O). In some embodiments, the one or more precursors comprising beta-diketonates of M or Ln may be useful precursor compositions for depositing MO or Ln₂O₃ in a cyclic ALD process in which reactive pulses of the beta-diketonate metal precursor alternate with pulses of O₃.

In some embodiments, one or more precursor ligands may be employed for deposition of the coating layer. In some embodiments, the one or more precursor ligands may comprise at least one of a hydrogen, a C₁-C₁₀ alkyl, which may be linear or branched, cyclic or acyclic, saturated or unsaturated; an aryl, a heterocycle, an alkoxy, a cycloalkyl, a silyl, a silylalkyl, a silylamide, a trimethylsilyl silyl-substituted alkyl, a trialkylsilyl-substituted alkyne, a trialkylsilylamido-substituted alkyne, a dialkylamide, an ethylene, an acetylene, an alkyne, a substituted alkene, a substituted alkyne, a diene, a cyclopentadienyl allene, an amine, an alkyl amine, a bidentate amine, an ammonia, a RNH₂ (where R is an organo, such as, for example, a hydrocarbyl, substituent), an amidinate, a guanidinate, a diazadiene cyclopentadienyl, an oxime, a hydroxyamine, an acetate, a beta-diketonate, a beta-ketoiminate, a nitrile, a nitrate, a sulfate, a phosphate, a halogen, a hydroxyl, a substituted hydroxyl, any derivative thereof, or any combination thereof.

In some embodiments, the forming may be performed at a temperature of 20° C. to 400° C., or any range or subrange therebetween. For example, in some embodiments, the forming may be performed at a temperature of 25° C. to 400° C., 50° C. to 400° C., 75° C. to 400° C., 100° C. to 400° C., 125° C. to 400° C., 150° C. to 400° C., 175° C. to 400° C., 200° C. to 400° C., 225° C. to 400° C., 250° C. to 400° C., 275° C. to 400° C., 300° C. to 400° C., 325° C. to 400° C., 350° C. to 400° C., 375° C. to 400° C., 20° C. to 375° C., 20° C. to 350° C., 20° C. to 325° C., 20° C. to 300° C., 20° C. to 275° C., 20° C. to 250° C., 20° C. to 225° C., 20° C. to 200° C., 20° C. to 175° C., 20° C. to 150° C., 20° C. to 125° C., 20° C. to 100° C., 20° C. to 75° C., 20° C. to 50° C., 125° C. to 375° C., 150° C. to 350° C., 175° C. to 350° C., 175° C. to 325° C., 200° C. to 350° C., 200° C. to 325° C., 225° C. to 350° C., 225° C. to 325° C., 250° C. to 350° C., 250° C. to 325° C., 275° C. to 350° C., 275° C. to 325° C., 300° C. to 350° C., 300° C. to 325° C., and/or any range or subrange therebetween.

In some embodiments, the deposition process is a process that forms a conformal coating layer. In some embodiments, a conformal coating layer may comprise a coating layer have a uniform or a substantially uniform thickness.

In some embodiments, the coating layer may have a thickness of 1 nm to 50 μm, or any range or subrange therebetween. For example, in some embodiments, the coating layer may have a thickness of less than 5 μm, less than 1 μm, or less than 250 nm. In some embodiments, the coating layer may have a thickness of 100 nm to 250 nm, 1 nm to 4 μm, 1 nm to 3 μm, 1 nm to 2 μm, 1 nm to 1 μm, 1 nm to 900 nm, 1 nm to 850 nm, 1 nm to 800 nm, 1 nm to 750 nm, 1 nm to 700 nm, 1 nm to 650 nm, 1 nm to 600 nm, 1 nm to 550 nm, 1 nm to 450 nm, 1 nm to 400 nm, 1 nm to 350 nm, 1 nm to 300 nm, 1 nm to 250 nm, 1 nm to 200 nm, 1 nm to 150 nm, 1 nm to 100 nm, 1 nm to 50 nm, 50 nm to 5 μm, 100 nm to 5 μm, 200 nm to 5 μm, 300 nm to 5 μm, 400 nm to 5 μm, 500 nm to 5 μm, 600 nm to 5 μm, 700 nm to 5 μm, 800 nm to 5 μm, 900 nm to 5 μm, 1 μm to 5 μm, 2 μm to 5 μm, 3 μm to 5 μm, 4 μm to 5 μm, 1 nm to 750 nm, 1 nm to 500 nm, 2 nm to 500 nm, 1 nm to 250 nm, 20 nm to 125 nm, 20 nm to 250 nm, 20 nm to 500 nm, 50 nm to 500 nm, 50 nm to 400 nm, 50 nm to 300 nm, 50 nm to 200 nm, 15 nm to 200 nm, 20 nm to 50 nm, 10 nm to 40 nm, 30 nm to 50 nm, 1 nm to 5 μm, 1 μm to 5 μm, 1 μm to 4 μm, 1 μm to 3 μm, 1 μm to 2 μm, 5 nm to 5 μm, 1 nm to 1 μm, and/or any range or subrange therebetween.

In some embodiments, the coating layer may comprise at least one second metal component. In some embodiments, the at least one second metal component may comprise, consist of, or consist essentially of at least one of elemental metal, a metal alloy, a metal compound (e.g., a metal oxide compound), or any combination thereof. In some embodiments, the at least one second metal component may comprise, consist of, or consist essentially of at least one of magnesium, aluminum, vanadium, iron, nickel, chromium, zinc, molybdenum, titanium, lithium, copper, manganese, or any combination thereof. In some embodiments, the at least one second metal component may be selected from the group consisting of at least one of magnesium, aluminum, vanadium, iron, nickel, chromium, zinc, molybdenum, titanium, lithium, copper, manganese, silicon, copper, manganese, magnesium oxide, or any combination thereof. In some embodiments, the at least one second metal component may comprise at least one metal that is the same as a metal included in the first metal component of the substrate. In some embodiments, for example, in some embodiments, the first metal component and the second component comprise aluminum, or any one or more of the other metals.

In some embodiments, the coating layer may comprise, consist of, or consist essentially of, or may be selected from the group consisting of, at least one of titania, yttria, alumina, zirconia, tantalum oxide, or any combination thereof. In some embodiments, the coating layer may comprise, consist of, or consist essentially of, or may be selected from the group consisting of, one or more of Al₂O₃; oxides of the formula MO, wherein M is Ca, Mg, or Be; oxides of the formula M′O₂, wherein M′ is a stoichiometrically acceptable metal; and oxides of the formula Re₂O₃, wherein Re is a rare earth element, such as, for example, a lanthanide element; and oxides of formula TaₓO_{y}, where x is greater than 0 and y is greater than 0. In some embodiments, the lanthanide element may comprise, consist of, or consist essentially of La, Sc, or Y. In some embodiments, the coating layer may comprise, consist of, or consist essentially of, or may be selected from the group consisting of, at least one of alumina, aluminum-oxy nitride, yttria, yttria-alumina, silicon oxide, silicon oxy-nitride, transition metal oxides, transition metal oxy-nitrides, rare earth metal oxides, rare earth metal oxy-nitrides, or any combination thereof. In some embodiments, the method further comprises fluorinating the coating layer to form a coating layer comprising at least one of YOF, YF₃, or any combination thereof.

In some embodiments, the coating layer is a conformal layer. In some embodiments, the coating layer is a layer having a substantially uniform thickness or a uniform thickness. In some embodiments, the coating layer may be a corrosion resistant layer or may form a corrosion resistant substrate surface. In some embodiments, the coating layer may be an etch resistant layer or may form an etch resistant substrate surface. In some embodiments, the coating layer may passivate the surface of the substrate. In some embodiments, the coating layer may be a protective layer. In some embodiments, the coating layer may impart at least one improved surface property.

Some embodiments relate to articles formed according to any of the methods disclosed herein. For example, in some embodiments, an article may comprise an additive manufactured three-dimensional (3D) body and a coating layer on a surface of the additive manufactured 3D body. It will be appreciated that the articles may comprise any of the features disclosed herein.

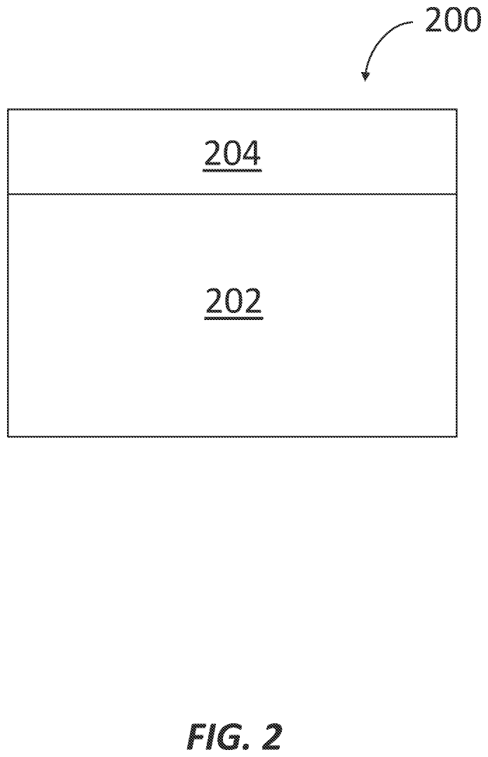

FIG. 2 is a schematic diagram of a cross-section of an article, according to some embodiments of the present disclosure. As shown in FIG. 2, the article 200 may comprise an additive manufactured 3D body 202 and a coating layer 204. In some embodiments, the coating layer 204 may comprise an ALD coating layer. In some embodiments, the coating layer 204 may comprise a thermal ALD coating layer. In some embodiments, the coating layer 204 may be formed on a surface of the additive manufactured 3D body 202.

The article 200 may have a characteristic of being biocompatible. That is, for example, in some embodiments, the article 200 is biocompatible. As used herein, the term “biocompatible” may refer to a material that is capable of functioning or existing in contact with biological fluid, tissue of a living organism, or any combination thereof, without having a negative effect on the living organism. In some embodiments, the term “biocompatible” refers to a material that is capable of functioning or existing in contact with biological fluid, tissue of a living organism, or any combination thereof, with a net beneficial effect on the living organism. Being biocompatible in some embodiments, the article 200 may be useful as a medical device or a portion of a medical device, among other things.

Accordingly, in some embodiments, the article 200 is a medical device. The medical device may comprise an additive manufactured three-dimensional (3D) body and a non-plasma coating layer on at least a portion of a surface of the additive manufactured 3D body. Any of the additive manufactured 3D bodies and non-plasma coating layers of this disclosure may be used herein. For example, in some embodiments, the additive manufactured 3D body has a monolithic structure. In some embodiments, the monolithic structure is not capable of construction by machining.

In some embodiments, the medical device is configured for implantation into a mammal. In some embodiments, the medical device is configured for temporary insertion into a mammal. In some embodiments, the medical device is configured for external use on a mammal. In some embodiments, the additive manufactured 3D body is biocompatible. In some embodiments, the additive manufactured 3D body is a body of the medical device. In some embodiments, the additive manufactured 3D body is a component of the medical device.

In some embodiments, the additive manufactured 3D body is at least one of a balloon, a graft, a stent, a catheter, a shunt, an embolic agent, a pacemaker, a defibrillator, an artificial implant, a prosthetic, a stimulator, a sensor, a wire, a lead, a valve, a plug, a pump, a filter, a mechanical connector, a tube, a plate, a surgical tool, an enclosure, any component thereof, or any combination thereof. In some embodiments, the additive manufactured 3D body is at least one of an angioplasty balloon, a valvuloplasty balloon, a deployment balloon, a pacemaker lead, a prosthetic heart valve, a vascular filter, a vascular plug, an artificial heart valve, an artificial heart, a catheter tip, a suture, a surgical staple, a screw, a nail, a bracket, a pin, a rod, a fixture, a guide wire, a drug pump, a synthetic vessel graft, a vascular graft, a nonvascular graft, a stent graft, a vascular stent, a coronary stent, a peripheral stent, an intraluminal paving stent, an arteriovenous shunt, an aneurysm filler, an implantable pulse generator, an implantable cardiac defibrillator, a cardioverter defibrillator, a spinal stimulator, a brain stimulator, a sacral nerve stimulator, a bone prosthetic, a joint prosthetic, a plastic tubing, a metal tubing, a dental braces, a hearing aid, a bandage, any component thereof, or any combination thereof.

In some embodiments, the additive manufactured 3D body comprises a structural component having an aspect ratio of 2:1 to 1000:1, wherein the aspect ratio is a ratio of two of a width, a depth, a height, or a diameter.

In some embodiments, the additive manufactured 3D body is an article of unitary construction. In some embodiments, the additive manufactured 3D body does not comprise seams. In some embodiments, the additive manufactured 3D body does not comprise braze joints. In some embodiments, the additive manufactured 3D body does not comprise weld joints.

In some embodiments, the non-plasma coating layer is a thermal atomic layer deposition (ALD) coating layer, a chemical vapor deposition (CVD) coating layer, or a solution deposition coating layer.

In some embodiments, the non-plasma coating layer comprises at least one of alumina, yttria, titania, zirconia, tantalum oxide, or any combination thereof.

In some embodiments, the non-plasma coating layer comprises at least one of YOF, YF₃, or any combination thereof.

In some embodiments, the non-plasma coating layer comprises at least one of: an oxide of formula MO, wherein M is Ca, Mg, or Be; an oxide of formula M′O₂, wherein M′ is a metal; an oxide of formula Re₂O₃, wherein Re is a rare earth element; an oxide of formula TaₓO_{y}, where x is greater than 0 and y is greater than 0; or any combination thereof.

In some embodiments, the non-plasma coating layer comprises at least one of an aluminum-oxy nitride; an yttria-alumina; a silicon oxide; a silicon oxy-nitride; a transition metal oxide; a transition metal oxy-nitride; a rare earth metal oxide; a rare earth metal oxy-nitrides; or any combination thereof.

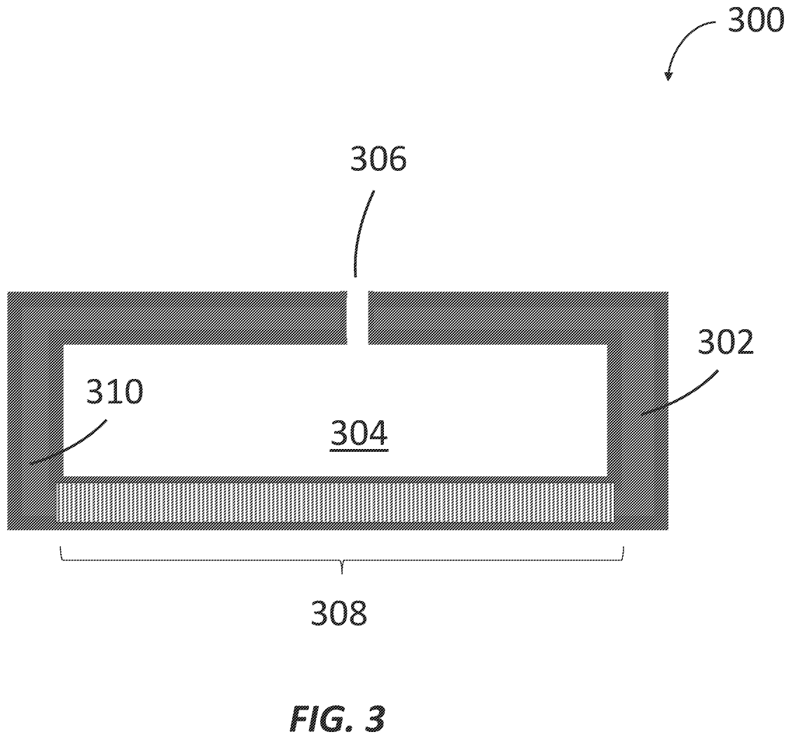

FIG. 3 is a schematic diagram of an article, according to some embodiments of the present disclosure. In some embodiments, the article 300 may be a component (e.g., a structure, a material, an apparatus, an equipment, etc.) used in semiconductor or microelectronic fabrication apparatuses, systems, components, parts, equipment, or processes. In some embodiments, the article 300 is a showerhead used to provide a processing gas onto a semiconductor wafer inside a process chamber. As shown in FIG. 3, the article 300 may comprise an additive manufactured 3D support structure 302 forming a cavity 304. In some embodiments, an opening 306 is formed in the cavity 304. In some embodiments, one or more process gases may flow through the opening 306 into the cavity 304. In some embodiments, the additive manufactured 3D support structure 302 further comprises a plurality of holes 308 through which the one or more process gases flow. As shown in FIG. 3, the shower head component may comprise a coating layer 310, such as an ALD coating layer or a thermal ALD coating layer. In some embodiments, the coating layer 310 is formed on all exposed surfaces of the shower head component.

What is claimed is:

1. A method for forming an article comprising:
forming a three-dimensional (3D) article by additive manufacturing to obtain an additive manufactured 3D article,
wherein the additive manufactured 3D article has a monolithic structure that is not capable of construction by machining; and
exposing the additive manufactured 3D article to one or more precursor gases to form a coating layer on a surface of the additive manufactured 3D article,
wherein the coating layer is formed by a non-plasma-based deposition process.

2. The method according to claim 1, wherein the additive manufactured 3D article having an aspect ratio of 5:1 to 1000:1, wherein the aspect ratio is a ratio of two of a width, a depth, a height, or a diameter.

3. The method according to claim 1, wherein the forming comprises dispensing a 3D printable material from a 3D printer to form the additive manufactured 3D article.

4. The method according to claim 3, wherein the 3D printable material comprises at least one of a metal powder, a metal alloy powder, a ceramic powder, a thermoplastic polymer, or any combination thereof.

5. The method according to claim 1, wherein the additive manufactured 3D article is an article of unitary construction.

6. The method according to claim 1, wherein the additive manufactured 3D article comprises at least one of a plenum, a trench, a structure defining a hole, a structure defining a channel, a structure defining a cavity, or any combination thereof.

7. The method according to claim 1, wherein the additive manufactured 3D article does not comprise seams.

8. The method according to claim 1, wherein the additive manufactured 3D article does not comprise braze joints.

9. The method according to claim 1, wherein the additive manufactured 3D article does not comprise weld joints.

10. The method according to claim 1, wherein the coating layer is formed by a thermal atomic layer deposition (ALD) process, a chemical vapor deposition (CVD) process, or a solution deposition process.

11. The method according to claim 1, wherein the coating layer comprises at least one of alumina, yttria, titania, zirconia, tantalum oxide, or any combination thereof.

12. The method according to claim 11, further comprising fluorinating the coating layer to form a coating layer comprising at least one of YOF, YF₃, or any combination thereof.

13. The method according to claim 1, wherein the coating layer comprises an oxide of formula MO, wherein M is Ca, Mg, or Be; an oxide of formula M′O₂, wherein M′ is a stoichiometrically acceptable metal; an oxide of formula Re₂O₃, wherein Re is a rare earth element; or an oxide of formula TaₓO_{y}, where x is greater than 0 and y is greater than 0.

14. The method according to claim 1, wherein the coating layer comprises an aluminum-oxy nitride; a yttria-alumina; a silicon oxide; a silicon oxy-nitride; a transition metal oxide; a transition metal oxy-nitride; a rare earth metal oxide; a rare earth metal oxy-nitrides; or any combination thereof.

15. A component of a semiconductor manufacturing tool comprising an article formed according to the method of claim 1.

16. An article comprising:
an additive manufactured three-dimensional (3D) body,
wherein the additive manufactured 3D body has a monolithic structure that is not capable of construction by machining; and
a coating layer on a surface of the additive manufactured 3D body,
wherein the coating layer is a non-plasma coating layer.

17. The article according to claim 16, wherein the additive manufactured 3D body has an aspect ratio of 2:1 to 1000:1, wherein the aspect ratio is a ratio of two of a width, a depth, a height, or a diameter.

18. The article according to claim 16, wherein the non-plasma coating layer is a thermal atomic layer deposition (ALD) coating layer.

19. The article according to claim 16, wherein the additive manufactured 3D body is a body of unitary construction.

20. The article according to claim 16, wherein the additive manufactured 3D article comprises at least one of a plenum, a trench, a structure defining a hole, a structure defining a channel, a structure defining a cavity, or any combination thereof.

21. A medical device comprising:
an additive manufactured three-dimensional (3D) body having a monolithic structure; and
a non-plasma coating layer on at least a portion of a surface of the additive manufactured 3D body.

22. The medical device according to claim 21, wherein the medical device is configured for implantation into a mammal.

23. The medical device according to claim 21, wherein the medical device is configured for temporary insertion into a mammal.

24. The medical device according to claim 21, wherein the medical device is configured for external use on a mammal.

25. The medical device according to claim 21, wherein the additive manufactured 3D body is biocompatible.

26. The medical device according to claim 21, wherein the additive manufactured 3D body is a body of the medical device.

27. The medical device according to claim 21, wherein the additive manufactured 3D body is a component of the medical device.

28. The medical device according to claim 21, wherein the additive manufactured 3D body is at least one of a balloon, a graft, a stent, a catheter, a shunt, an embolic agent, a pacemaker, a defibrillator, an artificial implant, a prosthetic, a stimulator, a sensor, a wire, a lead, a valve, a plug, a pump, a filter, a mechanical connector, a tube, a plate, a surgical tool, an enclosure, any component thereof, or any combination thereof.

29. The medical device according to claim 21, wherein the additive manufactured 3D body is at least one of an angioplasty balloon, a valvuloplasty balloon, a deployment balloon, a pacemaker lead, a prosthetic heart valve, a vascular filter, a vascular plug, an artificial heart valve, an artificial heart, a catheter tip, a suture, a surgical staple, a screw, a nail, a bracket, a pin, a rod, a fixture, a guide wire, a drug pump, a synthetic vessel graft, a vascular graft, a nonvascular graft, a stent graft, a vascular stent, a coronary stent, a peripheral stent, an intraluminal paving stent, an arteriovenous shunt, an aneurysm filler, an implantable pulse generator, an implantable cardiac defibrillator, a cardioverter defibrillator, a spinal stimulator, a brain stimulator, a sacral nerve stimulator, a bone prosthetic, a joint prosthetic, a plastic tubing, a metal tubing, a dental braces, a hearing aid, a bandage, any component thereof, or any combination thereof.

30. The medical device according to claim 21, wherein the additive manufactured 3D body comprises a structural component having an aspect ratio of 2:1 to 1000:1, wherein the aspect ratio is a ratio of two of a width, a depth, a height, or a diameter.

31. The medical device according to claim 21, wherein the additive manufactured 3D body is an article of unitary construction.

32. The medical device according to claim 21, wherein the additive manufactured 3D body does not comprise seams.

33. The medical device according to claim 21, wherein the additive manufactured 3D body does not comprise braze joints.

34. The medical device according to claim 21, wherein the additive manufactured 3D body does not comprise weld joints.

35. The medical device according to claim 21, wherein the non-plasma coating layer is a thermal atomic layer deposition (ALD) coating layer, a chemical vapor deposition (CVD) coating layer, or a solution deposition coating layer.

36. The medical device according to claim 21, wherein the non-plasma coating layer comprises at least one of alumina, yttria, titania, zirconia, tantalum oxide, or any combination thereof.

37. The medical device according to claim 21, wherein the non-plasma coating layer comprises at least one of YOF, YF₃, or any combination thereof.

38. The medical device according to claim 21, wherein the non-plasma coating layer comprises at least one of:
an oxide of formula MO, wherein M is Ca, Mg, or Be;
an oxide of formula M′O₂, wherein M′ is a metal;
an oxide of formula Re₂O₃, wherein Re is a rare earth element;
an oxide of formula TaₓO_{y}, where x is greater than 0 and y is greater than 0; or
any combination thereof.

39. The medical device according to claim 21, wherein the non-plasma coating layer comprises at least one of an aluminum-oxy nitride; an yttria-alumina; a silicon oxide; a silicon oxy-nitride; a transition metal oxide; a transition metal oxy-nitride; a rare earth metal oxide; a rare earth metal oxy-nitrides; or any combination thereof.

40. The medical device according to claim 21, wherein the monolithic structure is not capable of construction by machining.
